(19) United States
(12) Patent Application Publication
(10) Pub. No.: US 2015/0132959 A1
(43) Pub. Date: May 14, 2015

(54) PATTERN FORMATION AND TRANSFER DIRECTLY ON SILICON BASED FILMS

(71) Applicants: Leonard TEDESCHI, San Jose, CA (US); Srinivas NEMANI, Sunnyvale, CA (US)

(72) Inventors: Leonard TEDESCHI, San Jose, CA (US); Srinivas NEMANI, Sunnyvale, CA (US)

(21) Appl. No.: 14/075,971

(22) Filed: Nov. 8, 2013

(51) Int. Cl. H01L 21/308; H01L 21/67; H01L 21/02

(52) U.S. Cl. CPC H01L 21/3086; H01L 21/02274; H01L 21/02348; H01L 21/02351; H01L 21/67213; H01L 21/67063
USPC 438/694; 156/345.11; 156/345.1

(57) ABSTRACT

Embodiments involve patterned mask formation. In one embodiment, a method involves depositing a CVD film over a semiconductor wafer; exposing the CVD film to e-beam or UV radiation, forming a pattern in the CVD film; and etching the pattern in the CVD film, forming features in areas not exposed to the e-beam or UV radiation. In one embodiment, a method involves depositing a CVD film over a semiconductor wafer; depositing a thin photo-sensitive CVD hardmask film over the CVD film; exposing the thin photo-sensitive CVD hardmask film to e-beam or UV radiation, forming a pattern in the thin photo-sensitive CVD hardmask film; etching the pattern in the thin photo-sensitive CVD hardmask film; etching the pattern into the CVD film through the patterned thin photo-sensitive CVD hardmask film; and removing the patterned thin photo-sensitive CVD hardmask film.

### BACKGROUND

1) Field

Embodiments of the present invention pertain to the field of semiconductor processing, and more particularly, to forming patterned films.

2) Description of Related Art

In semiconductor processing, techniques for patterning films, such as low K films, are complex and typically involve a large number of processing steps. Patterning low K films using existing techniques involves a large number of processing steps because, at least in part, the selectivity between photoresist and low K materials is insufficient to directly pattern low K films. Therefore, additional sacrificial layers are deposited and patterned in order to pattern such films. For example, a dual damascene process for patterning trenches for copper filling can involve depositing a film to be patterned, depositing a hard mask, depositing an anti-reflective coating, depositing a photoresist, patterning the photoresist, patterning the hard mask through the photoresist, and patterning the film through the hard mask, and other processing steps (e.g., cleaning, and/or metrology and inspection for each operation).

The large number of processing steps results in a high defect rate, poor uniformity, and poor critical dimension (CD) control due to complications that can arise at each stage in the process. Additionally, existing techniques can damage the films during the patterning process. For example, the dielectric constant of low K films may be compromised during one or more etching processes. Furthermore, the large number of processing steps result in a higher cost process and waste of materials due to the deposition and etch of sacrificial layers (e.g., layers which are used during the process, but which do not ultimately form a part of the structures).

### SUMMARY

One or more embodiments of the invention are directed to forming patterned films over a substrate or semiconductor wafer.

In one embodiment, a method of forming a patterned chemical vapor deposition (CVD) film over a semiconductor wafer involves depositing the CVD film over the semiconductor wafer. The method involves exposing the CVD film to electron beam (e-beam) or UV radiation, forming a pattern in the CVD film. The method involves etching the pattern in the CVD film, forming features in areas not exposed to the e-beam or UV radiation.

In one such embodiment, the method involves depositing a second CVD film over the CVD film prior to etching the pattern. The method involves exposing the second CVD film to e-beam or UV radiation, forming a second pattern in the second CVD film. The method involves etching the pattern in the CVD film and the second pattern in the second CVD film, forming the features in the areas not exposed to the e-beam or UV radiation.

In one embodiment, a method involves forming the CVD film over the substrate, and forming a pattern in the CVD film with electron beam (e-beam) or UV radiation. The method involves developing the pattern in the CVD film with a dry etch chamber or wet etch solution to form features in areas not exposed to the e-beam or UV radiation.

In one embodiment, a system for forming a patterned CVD film over a semiconductor wafer includes a deposition chamber to deposit the CVD film over the semiconductor wafer. The system includes a patterning station to expose the CVD film to e-beam or UV radiation, forming a pattern in the CVD film. The system includes an etch chamber to etch the pattern in the CVD film, forming features in areas not exposed to the e-beam or UV radiation.

In one embodiment, a method of forming a patterned CVD film over a semiconductor wafer involves depositing the CVD film over the semiconductor wafer. The method involves depositing a thin photo-sensitive CVD hardmask film over the CVD film. The method involves exposing the thin photo-sensitive CVD hardmask film to electron beam (e-beam) or UV radiation, forming a pattern in the thin photo-sensitive CVD hardmask film. The method involves etching the pattern in the thin photo-sensitive CVD hardmask film. The method further involves etching the pattern into the CVD film through the patterned thin photo-sensitive CVD hardmask film. The method also involves removing the patterned thin photo-sensitive CVD hardmask film.

### BRIEF DESCRIPTION OF THE DRAWINGS

Embodiments of the present invention are illustrated by way of example, and not by way of limitation, and can be more fully understood with reference to the following detailed description when considered in connection with the figures in which:

FIG. 1A is a flow diagram of a method of forming a patterned chemical vapor deposition (CVD) film over a substrate or semiconductor wafer, in accordance with an embodiment of the present invention.

FIG. 1B is a flow diagram of a method of multiple-patterning, in accordance with an embodiment of the present invention.

FIGS. 2A, 2B, 2C, and 2D illustrate cross-sectional views of a substrate or semiconductor wafer during formation of a patterned CVD film, corresponding to operations of FIG. 1A, in accordance with an embodiment of the present invention.

FIGS. 2E, 2F, and 2G illustrate cross-sectional views of a substrate or semiconductor wafer during multiple-patterning, corresponding to operations of FIG. 1B, in accordance with an embodiment of the present invention.

FIG. 3 is a flow diagram of a method of forming multiple patterned CVD films over a substrate or semiconductor wafer, in accordance with an embodiment of the present invention.

FIGS. 4A, 4B, 4C, 4D, 4E, and 4F illustrate cross-sectional views of a substrate or semiconductor wafer during formation of multiple patterned CVD films, corresponding to operations of FIG. 3, in accordance with an embodiment of the present invention.

FIG. 5 is a flow diagram of a method of forming a patterned CVD film over a substrate or semiconductor wafer, in accordance with an embodiment of the present invention.

FIGS. 6A, 6B, 6C, 6D, 6E, and 6F illustrate cross-sectional views of a substrate or semiconductor wafer during formation of a patterned CVD film, corresponding to operations of FIG. 5, in accordance with an embodiment of the present invention.

FIGS. 7A and 7B are images of patterned CVD films, in accordance with embodiments of the present invention.

FIG. 8 illustrates a block diagram of a tool layout for forming a patterned CVD film, in accordance with an embodiment of the present invention.

FIG. 9 illustrates a block diagram of an exemplary computer system within which a set of instructions, for causing the computer system to perform any one or more of the methodologies discussed herein, may be executed.

### DETAILED DESCRIPTION

Apparatuses, systems, and methods of forming a patterned film are described.

One embodiment involves patterning directly on a chemical vapor deposition (CVD) film. For example, in one embodiment, a CVD chamber deposits a photo-sensitive film. An electron-beam (e-beam) or UV patterning system exposes the film to e-beam or UV radiation to form a pattern in the film. Exposure to the e-beam or UV radiation causes the exposed areas to become more or less resistant to etching. The system then develops the pattern (e.g., with a dry etch chamber or a wet etch bath). A curing chamber may cure the patterned CVD film. Thus, in one such embodiment, the system forms a pattern directly on a CVD film without sacrificial layers and the extra processing steps involved in existing methods.

In one such embodiment, prior to developing the pattern, the system can deposit a second photo-sensitive film, and expose the second film to e-beam or UV radiation to form a pattern in the second film. Developing the pattern can then involve developing the pattern in both the first and second films, forming multiple patterned films. Thus, the method can enable three-dimensional (3D) pattern formation with different chemical compositions.

In one embodiment, the method can enable multiple-patterning for low-pitch patterns. For example, after developing the pattern in the CVD film, a deposition chamber deposits a conformal film over the patterned CVD film. An etching chamber etches the layer to form spacers on the sidewalls of trenches in the CVD film. The system then etches the material between the spacers, leaving mandrels. Thus, the method can enable formation of a mandrel without deposition and etching of a sacrificial photoresist or hardmask layer.

One embodiment involves depositing a CVD film, and forming a thin photo-sensitive CVD hardmask film over the CVD film. An e-beam or UV patterning system exposes the thin photo-sensitive CVD hardmask film to e-beam or UV radiation to form a pattern in the thin photo-sensitive CVD hardmask film. The system then develops the pattern in the thin photo-sensitive CVD hardmask film, and etches the pattern into the CVD film through the patterned thin photo-sensitive CVD hardmask film. Finally, the system removes the patterned thin photo-sensitive CVD hardmask film. Thus, in one such embodiment, the method forms a patterned mask without multiple sacrificial layers.

In contrast to existing methods, embodiments enable forming patterned films with fewer processing steps, and with no or few sacrificial layers. Therefore, embodiments can enable lower cost pattern formation, lower defect rates, improved CD control, and/or reduced waste of materials.

In the following description, numerous specific details are set forth, such as specific techniques for forming films to be patterned, in order to provide a thorough understanding of embodiments of the present invention. It will be apparent to one skilled in the art that embodiments of the present invention may be practiced without these specific details. In other instances, well-known aspects, such as dry or wet etching, are not described in detail in order to not unnecessarily obscure embodiments of the present invention. Furthermore, it is to be understood that the various embodiments shown in the Figures are illustrative representations and are not necessarily drawn to scale.

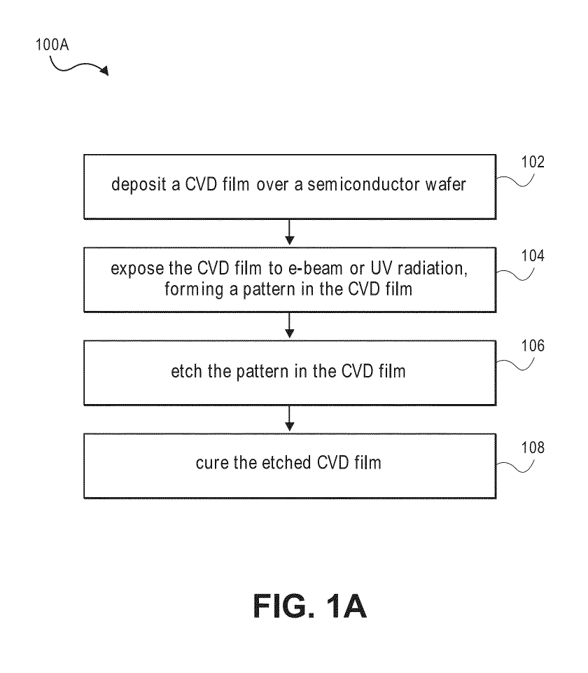

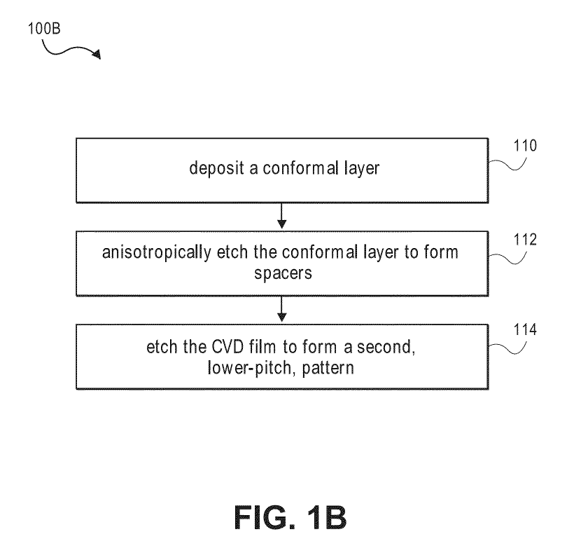

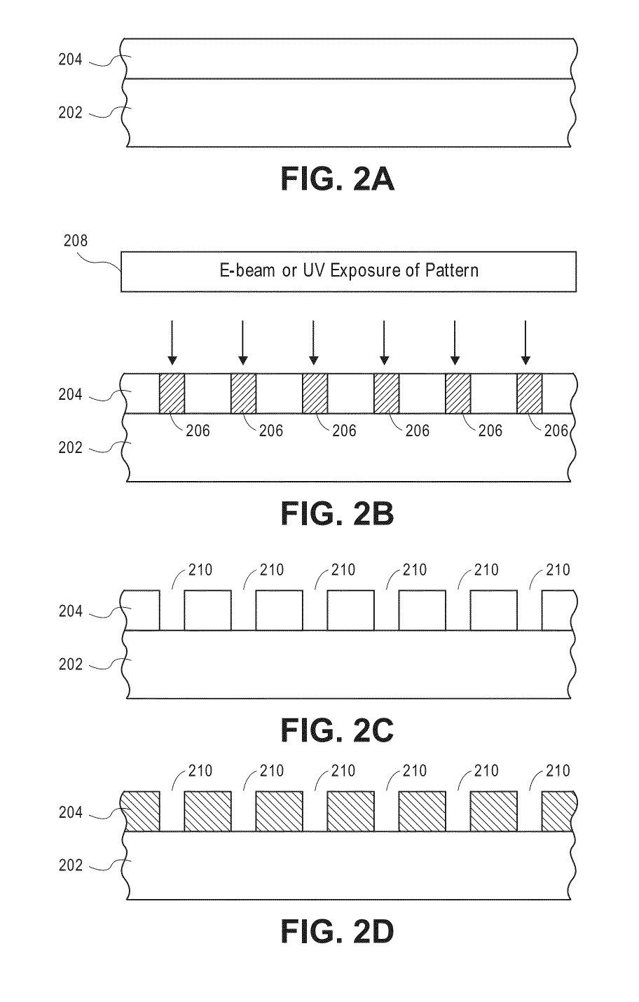

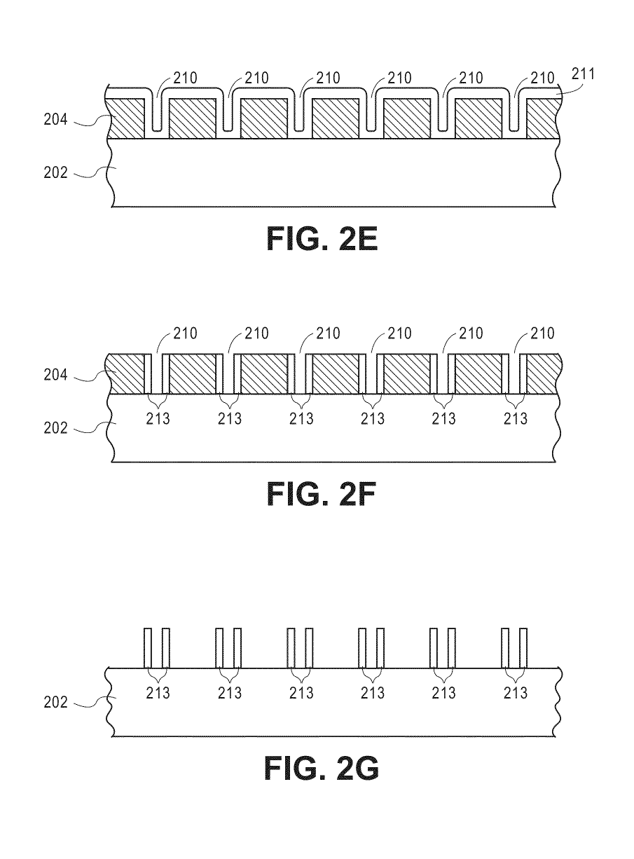

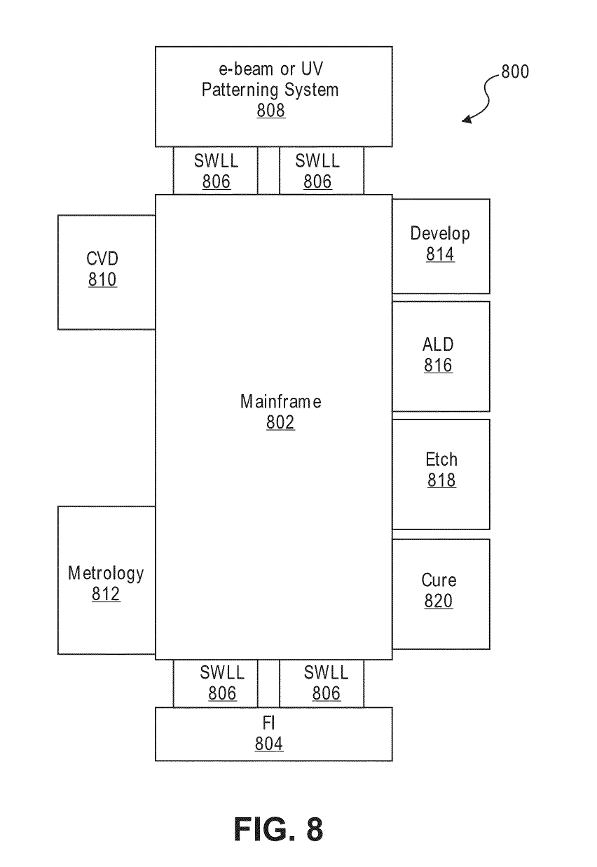

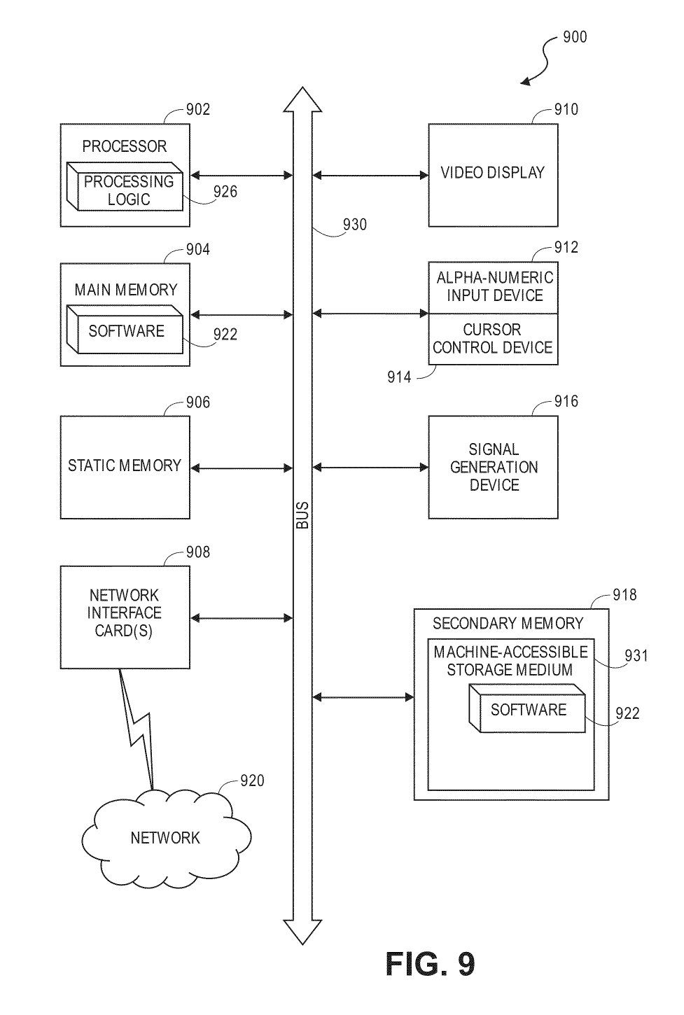

FIG. 1A is a flow diagram of a method of forming a patterned CVD film over a substrate or semiconductor wafer, in accordance with an embodiment of the present invention. The method 100A of FIG. 1A, as well as the other methods described herein, can be performed by a system such as the system 800 of FIG. 8 described below, and/or a computing system such as the system 900 of FIG. 9, which is also described below. FIGS. 2A, 2B, 2C, and 2D illustrate cross-sectional views of a substrate or semiconductor wafer during formation of a patterned CVD film, corresponding to operations of FIG. 1A, in accordance with an embodiment of the present invention.

The method 100A of FIG. 1A begins with a deposition chamber depositing a CVD film 204 over a semiconductor wafer or substrate 202, at operation 102. According to an embodiment, the CVD film 204 is a photo-sensitive film. Examples of CVD films include carbon doped oxides, SiₓN_{y} films, SiₓC_{y}N_{z} films, SiOₓ films, SiCOH films, dielectric films with loosely bonded carbon atoms, flowable CVD films, and/or other photo-sensitive films.

In one embodiment (e.g., where the CVD film 204 is a flowable CVD film), depositing the CVD film 204 involves introducing a reactive gas into a remote plasma chamber, and a precursor into a reaction chamber. The system then introduces, into the reaction chamber, radicals formed from the reactive gas in the remote plasma chamber to react with the precursor in the reaction chamber and form the CVD film 204 over the semiconductor wafer 202. For example, the system introduces a reactive gas such as oxygen (O), hydrogen (H), fluorine (F), or ammonia (NH₃) into a remote reactor, and introduces another precursor, such as an organosilane, into the reaction chamber. In one such example, the system uses octamethylcyclotetrasiloxane (OMCTS), with a remote oxygen plasma to form a low K film. In another example, the system uses trisilylamine (TSA) with a remote ammonia plasma to form a SiCN film. Another exemplary precursor that could be introduced into the reaction chamber is Tetraethyl orthosilicate (TEOS). The radicals formed in the remote plasma chamber and fed into the reaction chamber react with the other precursor in the reaction chamber, causing a film to condense on the surface of the wafer or substrate. Thus, the remote plasma chamber can enable forming flowable CVD films. In another embodiment, depositing the CVD film 204 involves depositing a CVD film with a plasma enhanced chemical vapor deposition (PECVD) chamber.

At operation 104, and corresponding to FIG. 2B, the system exposes the CVD film 204 to electron beam (e-beam) or UV radiation 208, forming a pattern 206 in the CVD film 204. Exposing the CVD film may involve, for example, direct writing the pattern 206 onto the CVD film 204 with an e-beam. In another example, exposing the CVD film involves exposing the CVD film 204 to UV light through a photomask. For example, in one embodiment, the system exposes the CVD film 204 to light having a wavelength in the range of 2 nm to 500 nm. Examples of wavelengths of light used to form a pattern in the CVD film include 248 nm and 193 nm. However, other wavelengths of light may be used. In an embodiment employing e-beam radiation, the dose, energy, and wavelength of the e-beam depends upon the properties of the film being irradiated, and the amount (e.g., thickness) of material to pattern.

Exposing a photo-sensitive film to radiation (e.g., UV, e-beam, or other radiation) promotes changes in the chemical or physical properties of the film. In contrast, exposing a photo-insensitive film to radiation does not typically result in significant changes in the chemical or physical properties of the film. An example of a chemical change is cross-linking within the material upon exposure to UV or e-beam radiation. According to an embodiment, exposure to UV or e-beam radiation changes the etch rate of the exposed areas. In one such embodiment, the etch rate of the exposed areas can be higher or lower than un-exposed areas, depending on the film properties.

At operation 106, and corresponding to FIG. 2C, the system develops the pattern in the CVD film 204 to form features 210. Developing the pattern may involve forming features such as trenches, holes (e.g., vias), peaks (e.g., mesas), or other features in areas exposed to the e-beam or UV radiation 208, or in areas not exposed to the e-beam or UV radiation 208. For example, if exposing the CVD film 204 to e-beam or UV radiation 208 makes the exposed regions more etch resistant, then developing the pattern results in trenches or holes in the areas not exposed to the radiation. If exposing the CVD film 204 to e-beam or UV radiation 208 increases the etch rate in the exposed regions, then developing the pattern results in trenches or holes in the areas not exposed to the radiation. FIG. 2C illustrates an example of an increased etch rate in the exposed areas of the film, resulting in trenches 210.

According to an embodiment, developing the pattern in the CVD film involves dry etching in a dry etch chamber, immersing the CVD film in a wet etchant, or by any other means of developing a pattern in the CVD film. Wet etching can include, for example, a TMAH wet bath, or other wet etching technique. Dry etching can include, for example, using a remote plasma etch chemistry, or other dry etching technique.

At operation 108, and corresponding to FIG. 2D, the system cures the etched CVD film 204. The cured film is illustrated by shading in the CVD film 204. Curing the etched CVD film 204 can include, for example, exposing the etched CVD film 204 to e-beam or UV radiation, or any other form of curing a CVD film. In one such example, the system exposes the etched CVD film 204 to light having a wavelength in a range of 120 nm to 1000 nm. Curing the CVD film 204 can increase stability of the film. Other embodiments may not include a curing operation.

The method 100A can also include a metrology operation after the etching operation 106, and/or after the curing operation 108, according to embodiments. For example, a metrology tool can measure the critical dimension (CD) of features making up the pattern.

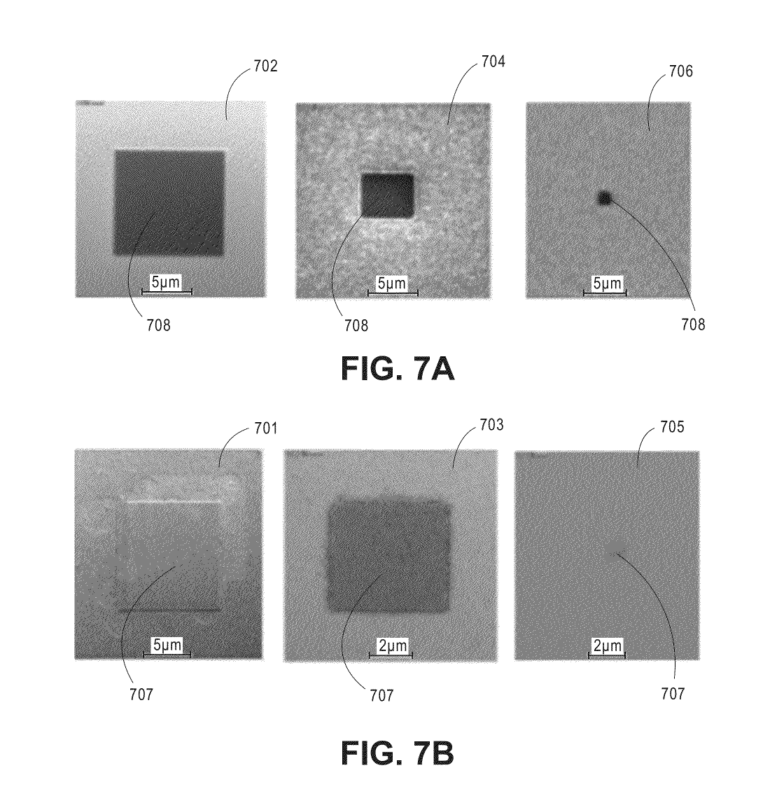

Thus, the method 100A illustrates an example of directly patterning a CVD film without requiring deposition and etching of sacrificial layers. FIGS. 7A and 7B are images of CVD films patterned with boxes using a method such as the method 100A. The images 702, 704, and 706 of FIG. 7A show low K films patterned with trenches 708 having diameters of 10 μm, 5 μm, and 1 μm, respectively. The images 701, 703, and 705 of FIG. 7B show SiCN films patterned with mesas 707 having diameters of 10 μm, 5 μm, and 1 μm, respectively. The patterns illustrated in the images of FIGS. 7A and 7B are examples. Other patterns and feature sizes are also possible with the methods described herein.

FIG. 1B is a flow diagram of a method 100B of multiple-patterning, which can produce low-pitch patterns, in accordance with an embodiment of the present invention. FIGS. 2E, 2F, and 2G illustrate cross-sectional views of a substrate or semiconductor wafer during multiple-patterning, corresponding to operations of FIG. 1B, in accordance with an embodiment of the present invention. The method 100B continues from operation 108 of FIG. 1A. Therefore, according to one embodiment, the method 100B begins with an etched and cured CVD film (e.g., the CVD film 204 of FIG. 2D). In another embodiment, the method 100B continues from operation 106 of FIG. 1A, and therefore begins with an etched (but not cured) CVD film (e.g., the CVD film 204 of FIG. 2C).

At operation 110, and corresponding to FIG. 2E, the system deposits a conformal layer 211 over the cured CVD film 204. According to an embodiment, the conformal layer 211 has an etch selectivity that is different than the CVD film 204 and the semiconductor wafer or substrate 202. The conformal layer 211 may include, for example, Si₃N₄, SO₂, TiOₓ, Al₂O₃, TiNₓ, or ZrOₓ, etc. The conformal layer 211 may be deposited by, for example, an atomic layer deposition (ALD) chamber, a CVD chamber, a spin-coating machine, or any other mechanism for depositing such a conformal layer.

At operation 112, and corresponding to FIG. 2F, the system anisotropically etches the conformal layer 211 to form spacers 213 on the sidewalls of the features 210 in the CVD film 204. The core material between the spacers 213 can be referred to as mandrels.

At operation 114, and corresponding to FIG. 2G, the system etches the CVD film 204 to remove core material between the spacers 213. The remaining spacers 213 form a second pattern that has a lower pitch than the pattern initially formed in the CVD film 204 by the features 210. The method 100B and the cross-sectional FIGS. 2E-2G illustrate an example of double-patterning. The method 100B may be repeated multiple times to perform further patterning, such as quad-patterning, to further reduce the pitch of the pattern. The method 100B may also include a metrology operation. For example, a metrology tool can measure the critical dimension (CD) of features making up the pattern.

In existing methods, mandrels are typically formed via a large number of processing operations including: depositing a hardmask, depositing a photoresist, patterning the photo resist, patterning the hardmask through the photoresist, etching the film through the hardmask to form the mandrels, depositing a conformal film, etching the conformal film to form spacers, and finally etching to remove the mandrels. Unlike existing methods, the embodiment illustrated in the method 100B and FIGS. 2E-2G enable mandrel formation without requiring the steps of depositing and etching a hardmask and photoresist.

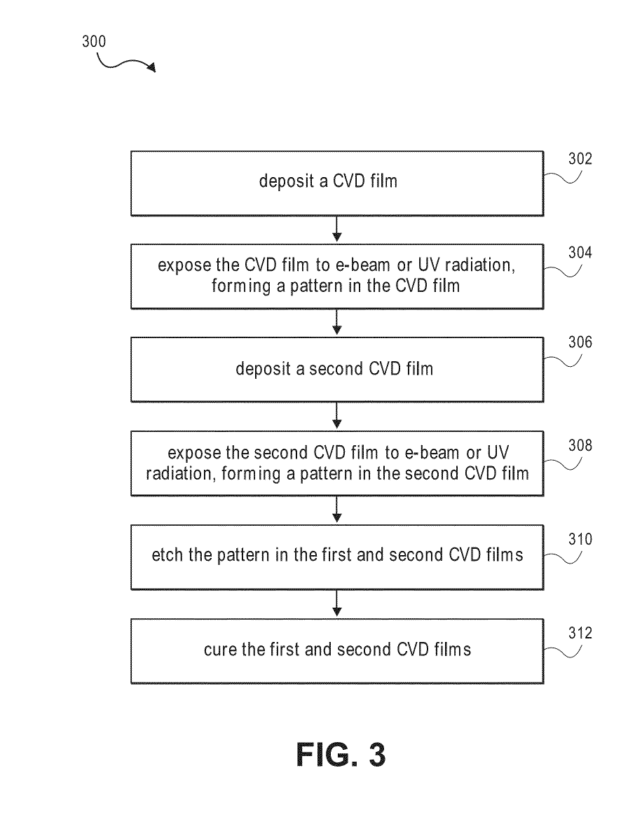

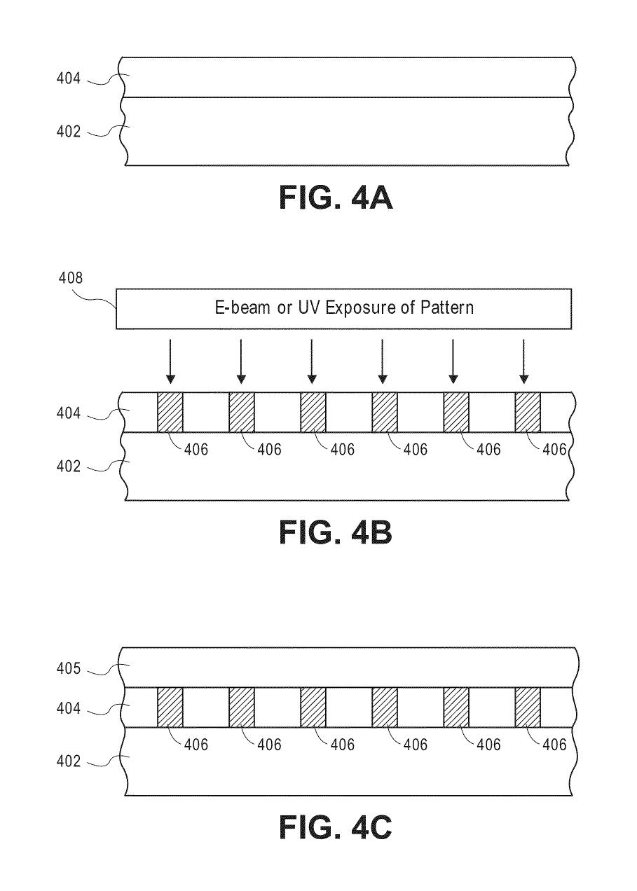

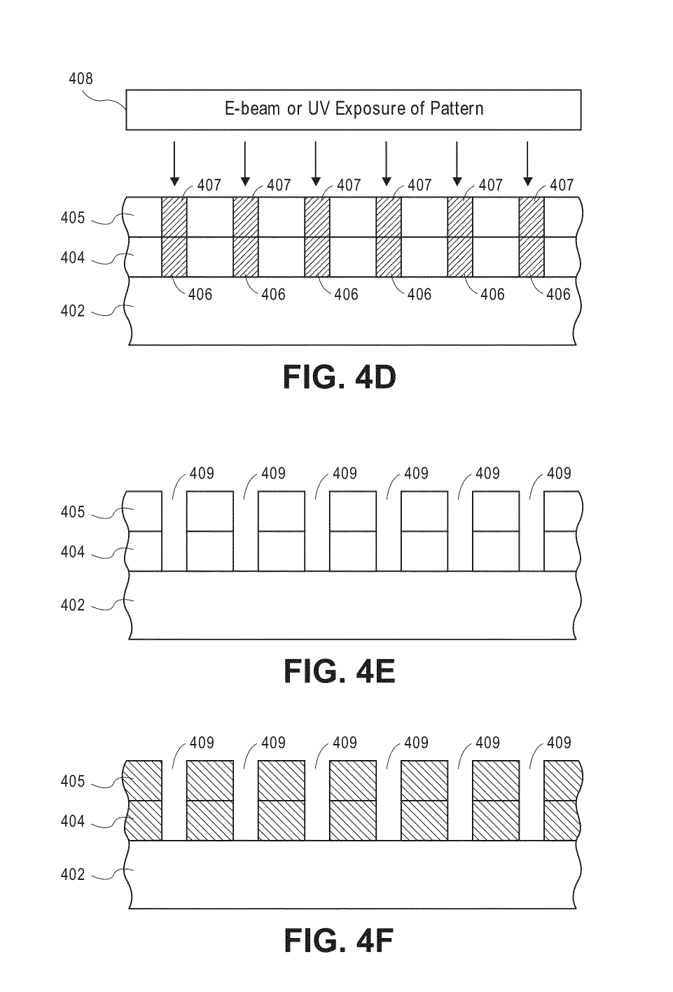

FIG. 3 is a flow diagram of a method 300 of forming multiple patterned CVD films (“3D pattern formation”) over a substrate or semiconductor wafer, in accordance with an embodiment of the present invention. FIGS. 4A, 4B, 4C, 4D, 4E, and 4F illustrate cross-sectional views of a substrate or semiconductor wafer during formation of multiple patterned CVD films, corresponding to operations of FIG. 3, in accordance with an embodiment of the present invention.

Similar to the method 100A, the method 300 begins with depositing a CVD film 404 over a semiconductor wafer or substrate 402 at operation 302. Also similar to method 100A, at operation 304, the system exposes the CVD film 404 to e-beam or UV radiation 408, forming a pattern 406 in the CVD film 404.

At operation 306, and corresponding to FIG. 4C, the system deposits a second CVD film 405 over the CVD film 404. The second CVD film 405 can have the same or a different chemical composition and properties than the first CVD film 404. For example, in one embodiment, the system can deposit a SiₓN_{y}H_{z} film using precursors such as trisilylamine (TSA) with remote argon plasma to form the CVD film 404 at operation 302. Then, at operation 306, the system can deposit a SiCN film using TSA with remote ammonia plasma to form the second CVD film 405. In another example, the CVD film 404 and the second CVD film 405 are both SiN films, but have different nitrogen concentrations. Other examples include low K films, SiN films, oxide films, or other combinations of films that are sensitive to e-beam or UV radiation.

At operation 308, and corresponding to FIG. 4D, the system exposes the second CVD film 405 to e-beam or UV radiation 408, forming a second pattern 407 in the second CVD film 405.

At operation 310, and corresponding to FIG. 4E, the system develops the pattern in the first and second CVD films 404 and 405. For example, the system etches the pattern in the CVD film and the second pattern in the second CVD film, forming the features 409. As explained above, the system can either form trenches or holes in the areas exposed to the e-beam or UV radiation, or in areas not exposed to the e-beam or UV radiation. FIG. 4F illustrates an example of an increased etch rate in the areas of the CVD films 404 and 405 exposed to the radiation.

At operation 312, and corresponding to FIG. 4F, the system cures both the CVD film 404 and the second CVD film 405.

In embodiments, the system performs multiple iterations of the operations 306 and 308 to deposit multiple films. As explained above, the films can have the same or different chemical compositions and properties. Thus, according to embodiments, the system can generate stacks of materials without requiring the deposition and patterning of a hardmask and photoresist layer.

The method 300 can also include a metrology operation as described above with respect to method 100A of FIG. 1A.

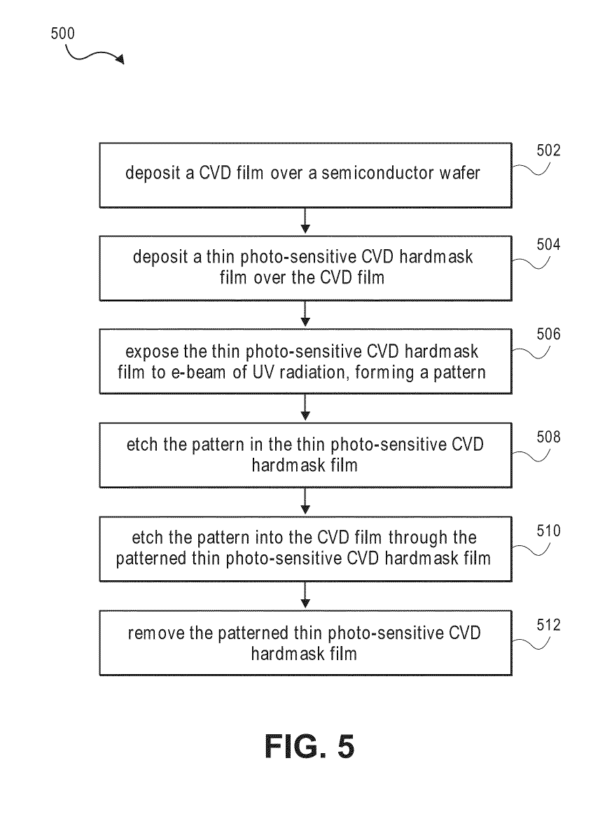

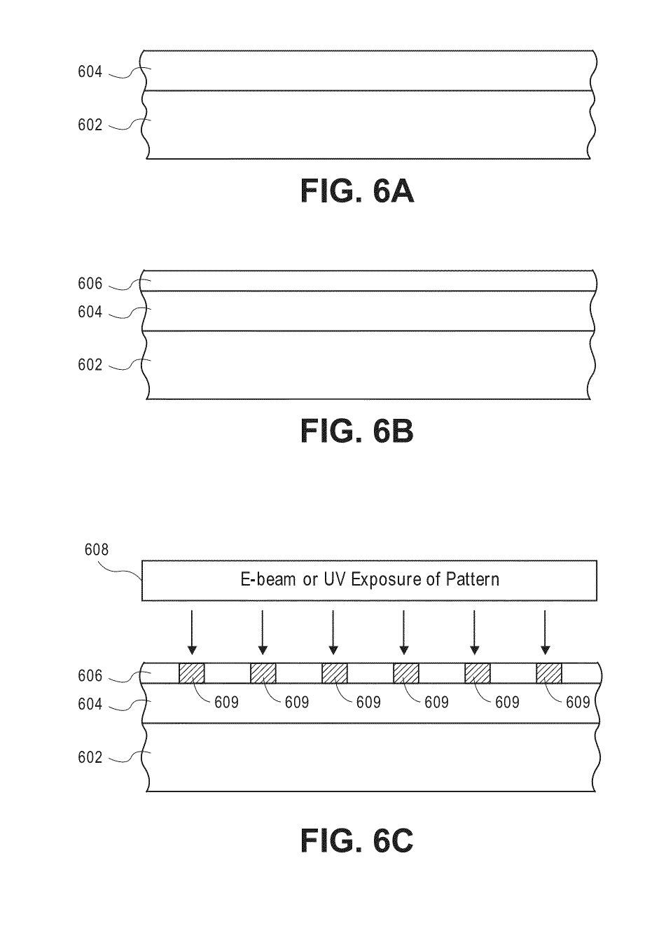

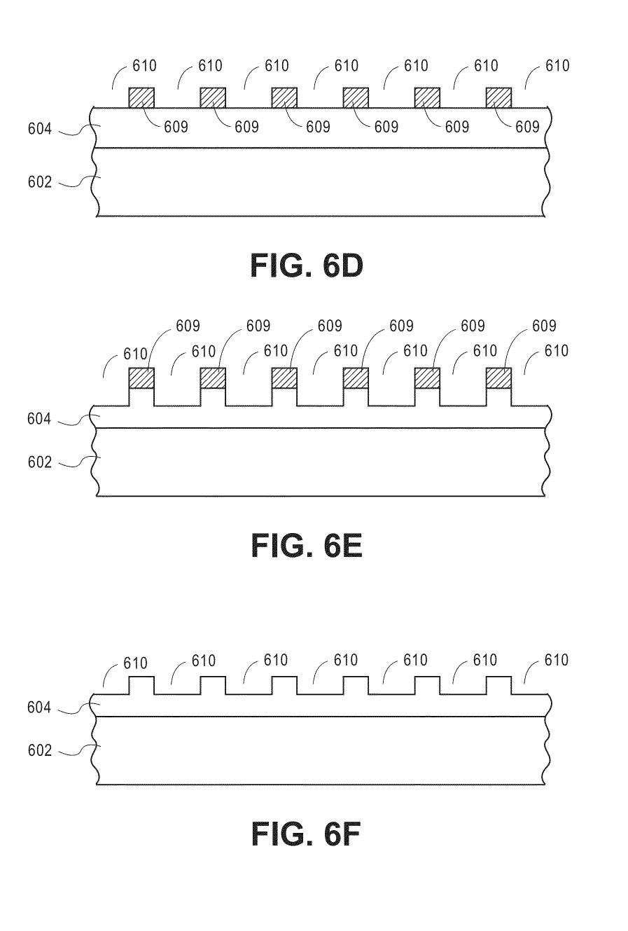

FIG. 5 is a flow diagram of a method 500 of forming a patterned CVD film over a substrate or semiconductor wafer, in accordance with an embodiment of the present invention. FIGS. 6A, 6B, 6C, 6D, 6E, and 6F illustrate cross-sectional views of a substrate or semiconductor wafer during formation of a patterned CVD film, corresponding to operations of FIG. 5, in accordance with an embodiment of the present invention.

According to one embodiment, the method 500 of FIG. 5 involves patterning a CVD film through a very thin photo-sensitive CVD hardmask formed directly on the CVD film to be patterned. In one such embodiment, the system removes the thin photo-sensitive CVD hardmask film after patterning the CVD film, making the thin photo-sensitive CVD hardmask film a sacrificial film. Unlike existing methods, which typically require deposition and patterning of multiple sacrificial layers to pattern a CVD film, in one embodiment, the system can pattern a CVD film with one patterned thin photo-sensitive CVD hardmask film. Furthermore, in one embodiment, the thin photo-sensitive CVD hardmask film is formed from smaller molecules and is thinner than existing films for patterning CVD films. Therefore, in one such embodiment, the method enables reduced line edge roughness and an increased lithographic process window.

The method 500 begins with the system depositing a CVD film 604 over a semiconductor wafer or substrate 602. The CVD film 604 can include, for example, a dielectric film, a low K film, or any other film to be patterned. In one embodiment, the CVD film 604 is an anti-reflective film. According to an embodiment, the CVD film 604 is photo-insensitive.

At operation 504, and corresponding to FIG. 6B, the system deposits a thin photo-sensitive CVD hardmask film 606 over the CVD film 604. In one embodiment, the system deposits the thin photo-sensitive CVD hardmask film 606 towards the end of the process of depositing the CVD film 604. For example, the system can deposit the CVD film 604 over the semiconductor wafer or substrate 602 in a deposition chamber, and deposit the thin photo-sensitive CVD hardmask film 606 by changing the chemistry in the chamber.

In one embodiment, changing the chemistry in the chamber may involve introducing different or additional precursors into the chamber to deposit the thin photo-sensitive CVD hardmask film 606. According to one embodiment, changing the chemistry in the chamber after depositing the CVD film 604 involves introducing different or additional precursors into the chamber to change a surface chemistry of the CVD film 604, forming the thin photo-sensitive CVD hardmask film 606 in a top layer of the CVD film 604. Thus, according to one embodiment, the thin photo-sensitive CVD hardmask film 606 is formed in the same deposition chamber as the CVD film 604. The deposition chamber to deposit the films 604 and 606 can include, for example, a plasma-enhanced CVD chamber. Exemplary precursors include TSA and argon to form a SiₓN_{y}H_{z} film, but any suitable precursors for forming a thin photo-sensitive CVD hardmask film may be used. In one embodiment, the deposited thin photo-sensitive CVD hardmask film has a thickness in the range of 100-500 Angstroms.

At operation 506, and corresponding to FIG. 6C, the system exposes the thin photo-sensitive CVD hardmask film 606 to e-beam or UV radiation 608, forming a pattern 609 in the thin photo-sensitive CVD hardmask film 606. In one embodiment, patterning the thin photo-sensitive CVD hardmask film 606 involves exposing the thin photo-sensitive CVD hardmask film 606 to UV light having a wavelength in a range of 2 nm to 500 nm. Examples of wavelengths of light used to form a pattern in the CVD film include 248 nm and 193 nm. However, other wavelengths of light may be used. In one embodiment, patterning the thin photo-sensitive CVD hardmask film 606 involves direct writing the pattern onto the thin photo-sensitive CVD hardmask film with an e-beam.

At operation 508, and corresponding to FIG. 6D, the system develops the pattern. According to an embodiment, developing the pattern in the thin photo-sensitive CVD hardmask film involves dry etching in a dry etch chamber, immersing the thin photo-sensitive CVD hardmask film in a wet etchant, or by any other means of developing a pattern in the film. Developing the pattern in the thin photo-sensitive CVD hardmask film results in features 610. FIG. 6D shows an example of a decreased etch rate in the areas of the thin photo-sensitive CVD hardmask film exposed to radiation.

At operation 510, and corresponding to FIG. 6E, the system etches the pattern into the CVD film 604 through the patterned thin photo-sensitive CVD hardmask film.

At operation 512, and corresponding to FIG. 6F, the system removes the patterned thin photo-sensitive CVD hardmask film. Removing the patterned thin photo-sensitive CVD hardmask film can involve a plasma etch, wet etch, or any other method of removing a thin photo-sensitive CVD hardmask film.

In embodiments, multiple-patterning may further be performed (e.g., in accordance with the method 100B of FIG. 1B above). The method 500 can also include a metrology operation as described above with reference to the method 100A of FIG. 1A.

Thus, the method 500 of FIG. 5 illustrates another example of forming a patterned CVD film.

FIG. 8 illustrates a block diagram of a tool layout for forming a patterned CVD film, in accordance with embodiments of the present invention. The illustrated system 800 is in a cluster configuration that includes a centrally located mainframe 802 coupled with a factory interface 804 (FI) having a plurality of load locks 806 (e.g., single wafer load locks (SWLLs)). According to an embodiment, the mainframe 802 is a vacuum (e.g., <1 torr). The factory interface 804 may be a suitable atmospheric port to interface between an outside manufacturing facility and the system 800. The factory interface 804 may include robots with arms or blades for transferring substrates (or carriers thereof) from storage units (such as front opening unified pods) into the mainframe 802.

The system 800 includes a chemical vapor deposition (CVD) chamber 810 to deposit films over a semiconductor or wafer. For example, the CVD chamber 810 can deposit a CVD film such as in the operation 102 of FIG. 1A, the operation 302 of FIG. 3, and the operations 502 and 504 of FIG. 5.

The CVD chamber 810 can include a flowable CVD chamber with a remote plasma reactor. For example, in one such embodiment, a remote plasma chamber formed radicals from a reactive gas, and the radicals are fed into a reaction chamber with a precursor to form the CVD film over the semiconductor wafer or substrate. Thus, the precursor introduced into the chamber does not pass through the plasma environment. In one such example, the radicals react with the other precursor that was introduced into the chamber, resulting in polymerization of the other precursor and condensation on the wafer. One such embodiment results in deposition of a flowable CVD film over the wafer surface. In another embodiment, the CVD chamber 810 is a plasma enhanced chemical vapor deposition (PECVD) chamber.

The system 800 also includes an e-beam or UV patterning system 808, which is coupled with the mainframe 802 via load locks 806, according to an embodiment. The patterning station exposes the CVD film to e-beam or UV radiation, forming a pattern in the CVD film. For example, the e-beam or UV patterning station 808 can be used to form a pattern such as in the operation 104 of FIG. 1A, the operation 308 of FIG. 3, and the operation 506 of FIG. 5.

A develop chamber 814 develops the pattern in one or more CVD films. The develop chamber 814 may be used to develop patterns such as in operation 106 of FIG. 1A, operation 310 of FIG. 3, and operation 508 of FIG. 5, In one embodiment, the develop chamber is a dry etch chamber. In another embodiment, the develop chamber is a wet etch chamber.

In one embodiment, the system further includes a curing station to cure the etched CVD film. The curing station 820 can harden or stabilize the developed film, such as in the operation 108 of FIGS. 1 and 312 of FIG. 3.

In one embodiment, the system 800 includes an atomic layer deposition (ALD) chamber 816 to deposit a conformal layer over the cured CVD film. For example, an embodiment such as the method 100B of FIG. 1B may employ an ALD chamber to form a conformal film such as the film 211 in FIG. 2E. Such an embodiment may also include a second etch chamber 818 to anisotropically etch the conformal layer to form spacers on sidewalls of the features in the CVD film. The second etch chamber 818 can also etch the CVD film to remove material between the spacers, forming a second pattern having a lower pitch than the pattern.

According to an embodiment, the system 800 includes a metrology tool 812. The metrology tool 812 evaluates the features and pattern formed by the processing chambers. For example, the metrology tool 812 can measure the critical dimension (CD) of features formed after development by the develop chamber 814, etching by the etch chamber 818, and/or curing by the curing station 820.

FIG. 9 illustrates a computer system 900 within which a set of instructions, for causing the machine to execute one or more of the scribing methods discussed herein may be executed. The exemplary computer system 900 includes a processor 902, a main memory 904 (e.g., read-only memory (ROM), flash memory, dynamic random access memory (DRAM) such as synchronous DRAM (SDRAM) or Rambus DRAM (RDRAM), etc.), a static memory 906 (e.g., flash memory, static random access memory (SRAM), etc.), and a secondary memory 918 (e.g., a data storage device), which communicate with each other via a bus 930.

Processor 902 represents one or more general-purpose processing devices such as a microprocessor, central processing unit, or the like. More particularly, the processor 902 may be a complex instruction set computing (CISC) microprocessor, reduced instruction set computing (RISC) microprocessor, very long instruction word (VLIW) microprocessor, etc. Processor 902 may also be one or more special-purpose processing devices such as an application specific integrated circuit (ASIC), a field programmable gate array (FPGA), a digital signal processor (DSP), network processor, or the like. Processor 902 is configured to execute the processing logic 926 for performing the operations and steps discussed herein.

The computer system 900 may further include a network interface device 908. The computer system 900 also may include a video display unit 910 (e.g., a liquid crystal display (LCD) or a cathode ray tube (CRT)), an alphanumeric input device 912 (e.g., a keyboard), a cursor control device 914 (e.g., a mouse), and a signal generation device 916 (e.g., a speaker).

The secondary memory 918 may include a machine-accessible storage medium (or more specifically a computer-readable storage medium) 931 on which is stored one or more sets of instructions (e.g., software 922) embodying any one or more of the methodologies or functions described herein. The software 922 may also reside, completely or at least partially, within the main memory 904 and/or within the processor 902 during execution thereof by the computer system 900, the main memory 904 and the processor 902 also constituting machine-readable storage media. The software 922 may further be transmitted or received over a network 920 via the network interface device 908.

While the machine-accessible storage medium 931 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention.

For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

Thus, systems, apparatuses, and method of forming patterned CVD films are described. Embodiments enable transferring a pattern to a CVD film without a mask, or with a thin photo-sensitive CVD hardmask formed directly on the CVD film to be patterned. Therefore, embodiments enable less complex pattern transfer with fewer process operations and sacrificial layers. Fewer process operations enables improved yield, reduced costs and waste of materials, and/or faster cycle time.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

What is claimed is:

1. A method of forming a patterned chemical vapor deposition (CVD) film over a semiconductor wafer, the method comprising:
depositing the CVD film over the semiconductor wafer;
exposing the CVD film to electron beam (e-beam) or UV radiation, forming a pattern in the CVD film; and
etching the pattern in the CVD film, forming features in areas not exposed to the e-beam or UV radiation.

2. The method of claim 1, wherein depositing the CVD film over the semiconductor wafer comprises:
introducing a reactive gas into a remote plasma chamber;
introducing a precursor into a reaction chamber; and
introducing, into the reaction chamber, radicals formed from the reactive gas in the remote plasma chamber to react with the precursor in the reaction chamber and form the CVD film over the semiconductor wafer.

3. The method of claim 1, wherein depositing the CVD film over the semiconductor wafer comprises depositing the CVD film with a plasma enhanced chemical vapor deposition (PECVD) chamber.

4. The method of claim 1, wherein the CVD film is a low K film.

5. The method of claim 1, wherein exposing the CVD film comprises direct writing the pattern onto the CVD film with an e-beam.

6. The method of claim 1, wherein exposing the CVD film comprises exposing the CVD film to UV light having a wavelength in a range of 2 nm to 500 nm.

7. The method of claim 1, wherein etching the pattern in the CVD film comprises dry etching the CVD film.

8. The method of claim 1, wherein etching the pattern in the CVD film comprises immersing the CVD film in a wet etchant.

9. The method of claim 1, further comprising:
curing the etched CVD film with e-beam radiation.

10. The method of claim 1, further comprising:
curing the etched CVD film with exposure to light having a wavelength 120 nm to 1000 nm.

11. The method of claim 1, further comprising:
depositing a second CVD film over the CVD film prior to etching the pattern;
exposing the second CVD film to e-beam or UV radiation, forming a second pattern in the second CVD film; and
etching the pattern in the CVD film and the second pattern in the second CVD film, forming the features in the areas not exposed to the e-beam or UV radiation.

12. The method of claim 11, wherein the CVD film and the second CVD film have different chemical compositions.

13. The method of claim 1, further comprising:
depositing a conformal layer over the etched CVD film;
anisotropically etching the conformal layer to form spacers on sidewalls of the features in the CVD film; and
etching the CVD film to remove material between the spacers, forming a second pattern with a lower pitch than the pattern.

14. A method of forming a patterned chemical vapor deposition (CVD) film over a substrate, the method comprising:
forming the CVD film over the substrate;
forming a pattern in the CVD film with electron beam (e-beam) or UV radiation;
developing the pattern in the CVD film with a dry etch chamber or wet etch solution to form features in areas not exposed to the e-beam or UV radiation; and
curing the developed CVD film.

15. The method of claim 14, further comprising:
forming a second CVD film over the CVD film prior to developing the pattern;
forming a second pattern in the second CVD film with e-beam or UV radiation;
developing the pattern in the CVD film and the second pattern in the second CVD film to form the features in the areas not exposed to the e-beam or UV radiation; and
curing both the CVD film and the second CVD film.

16. The method of claim 14, further comprising:
forming a conformal layer over the cured CVD film;
anisotropically etching the conformal layer to form spacers on sidewalls of the features in the CVD film; and
etching the CVD film to remove material between the spacers, forming a second pattern with a lower pitch than the pattern.

17. A system for forming a patterned chemical vapor deposition (CVD) film over a semiconductor wafer, the system comprising:
a deposition chamber to deposit the CVD film over the semiconductor wafer;
a patterning station to expose the CVD film to e-beam or UV radiation, forming a pattern in the CVD film; and
an etch chamber to etch the pattern in the CVD film, forming features in areas not exposed to the e-beam or UV radiation.

18. The system of claim 17, further comprising:
an atomic layer deposition chamber to deposit a conformal layer over the etched CVD film; and
a second etch chamber to anisotropically etch the conformal layer to form spacers on sidewalls of the features in the CVD film;
wherein the second etch chamber is to etch the CVD film to remove material between the spacers, forming a second pattern having a lower pitch than the pattern.

19. The system of claim 17, wherein the deposition chamber comprises a remote plasma chamber to form radicals from a reactive gas, wherein the radicals are fed into a reaction chamber with a precursor to form the CVD film over the semiconductor wafer.

20. The system of claim 17, wherein the deposition chamber comprises a plasma enhanced chemical vapor deposition (PECVD) chamber.
